(19) United States
(12) Patent Application Publication
(10) Pub. No.: US 2010/0038752 A1
(43) Pub. Date: Feb. 18, 2010

(54) MODULAR & SCALABLE INTRA-METAL CAPACITORS

(75) Inventors: Chit Hwei NG, Singapore (SG); Chaw Sing HO, Singapore (SG); Kerwin KHU, Singapore (SG); Sanford CHU, Singapore (SG)

Correspondence Address: HORIZON IP PTE LTD, 7500A Beach Road, #04-306/308 The Plaza, SINGAPORE 199591, SG

(73) Assignee: CHARTERED SEMICONDUCTOR MANUFACTURING, LTD., Singapore (SG)

(21) Appl. No.: 12/192,131

(22) Filed: Aug. 15, 2008

(51) Int. Cl. H01L 29/00; H01G 4/005; H01L 21/20

(52) U.S. Cl. 257/532; 361/303; 438/381; 257/E29.029; 257/E21.661

(57) ABSTRACT

An intra-metal capacitor unit cell comprises a first electrode and a second electrode formed in the same device layer. A dielectric layer separates the electrodes. The first electrode is substantially surrounded by the second electrode. Misalignment between the first and second electrodes does not substantively alter the capacitance of the unit cell.

### FIELD OF THE INVENTION

The present invention relates generally to integrated circuits (ICs), and more particularly to intra-metal capacitors.

### BACKGROUND OF THE INVENTION

Passive components such as transistors, resistors and capacitors are typically incorporated in ICs to perform various functions. Capacitors, for instance, can be used to store energy or as filters for differentiating between high- and low-frequency signals. On-chip capacitors are conventionally formed as multi-level interconnects structures consisting of stacked electrodes separated by a dielectric layer. The electrodes typically comprise conducting material, for example, doped polysilicon, or metals such as copper (Cu) or aluminum.

One type of capacitors used in ICs is the intrametal capacitor. An advantage of intrametal capacitors is that they are formed in the same metal layers used to form metal lines, avoiding the need for additional processes or masks. Typically, the electrodes of a capacitor are formed on two adjacent metal layers with the capacitor electrodes being separated by an inter-metal dielectric (IMD) layer. The capacitors can have layouts or designs such as straight metal fingers, serpentine line or fractal designs.

However, conventional intrametal capacitor designs have drawbacks. For example, curvy, serpentine, fringed or fractal designs make accurate prediction of capacitance difficult. Also straight metal line capacitors are prone to capacitance fluctuations. Changes in capacitance can arise from, for example, variation in the Cu chemical mechanical polishing (CMP) process used to level the capacitor electrodes. In particular, over-polish can cause dishing in extended or large copper areas, reducing the effective electrode area, thereby leading to an increase in capacitance. Misalignment of electrodes can also cause capacitance fluctuations.

From the foregoing discussion, it is desirable to provide a capacitor with accurate and predictable capacitance.

### SUMMARY OF THE INVENTION

The present invention relates to intra-metal capacitors. In accordance with one embodiment of the invention, the intra-metal capacitor comprises a first electrode and a second electrode substantially surrounding the first electrode. The first and second electrodes are formed in a device layer. The intra-metal capacitor further comprises a dielectric layer separating the first and second electrodes in the device layer.

In accordance with another embodiment of the invention, a semiconductor structure having a contact, the structure comprising a plurality of unit cells, is provided. Each unit cell comprises an intra-metal capacitor having a unit capacitance and the unit cells are arranged to provide an overall capacitance.

In accordance with yet another embodiment of the invention, an IC comprising an intra-metal capacitor is provided. The intra-metal capacitor comprises a first electrode, a second electrode substantially surrounding the first electrode, and a dielectric layer disposed in the space between the first and second electrodes. An increase in the space between the electrodes on any one side results in a corresponding decrease on the opposite side.

In accordance with one aspect of the invention, a method of forming an intra-metal capacitor is provided. The method comprises providing a first electrode and a second electrode substantially surrounding the first electrode. The first and second electrodes are formed in a device layer. A dielectric layer separating the first and second electrodes in the device layer is also provided.

These and other objects, along with advantages and features of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. Various embodiments of the present invention are described with reference to the following drawings, in which:

FIG. 1 shows a capacitor unit cell according to one embodiment of the invention;

FIGS. 2a-b show capacitors having a plurality of unit cells according to alternative embodiments of the invention;

FIGS. 3a-b show a table and plot, respectively, of simulated capacitances of capacitors having different numbers of unit cells; and

FIGS. 4a-b show capacitors in accordance with other embodiments of the invention.

### DETAILED DESCRIPTION OF THE INVENTION

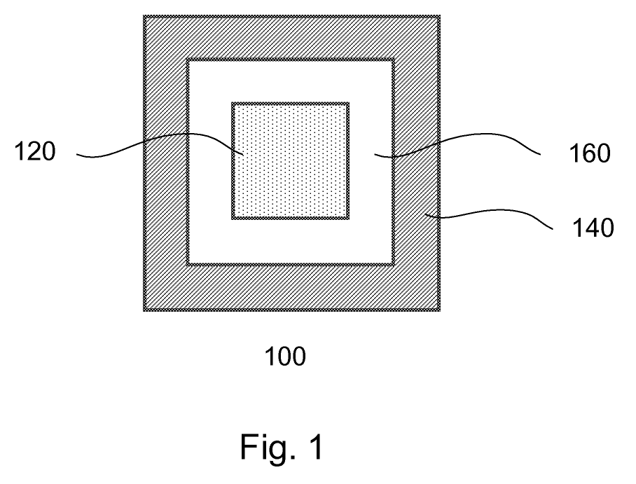

FIG. 1 shows a top view of a capacitor 100 in accordance with one embodiment of the invention. The capacitor comprises first and second electrodes 120 and 140 formed in the same device layer, and separated by a capacitor dielectric 160. The electrodes comprise a conductive material. Various types of conductive materials can be used to form the electrodes. For example, copper, aluminum, doped polysilicon or other metals, alloys or conductive materials can also be used. The capacitor dielectric can be formed from a dielectric material such as silicon oxide. The silicon oxide can be doped or undoped. Other types of capacitor dielectric materials, such as silicon nitride, low-k dielectrics or ultra low-k dielectrics, are also useful. Preferably, the first and second electrodes are formed from the same material. Preferably, the electrodes are formed on the same conductive or metal layer of an IC. For example, the electrodes are formed on the same conductive or metal layer with the same material, resulting in an intra-metal capacitor. It is understood that the capacitor can be formed on any metal layer of the IC. Forming first and second electrodes from different materials is also useful.

In one embodiment, the first (internal) electrode is substantially encompassed within or surrounded by the second (external) electrode, forming a unit capacitor or cell. Preferably, the first electrode is encompassed within or surrounded by the second electrode. In such case, an increase in the space between the electrodes on any one side results in a corresponding decrease on the opposite side. As such, misalignment between the first and second electrodes will not substantially alter the capacitance of the unit capacitor, which enables tighter capacitance control. Providing a first electrode partially surrounded or enclosed by a second electrode is also useful. As shown, the electrodes comprise a square shape. Other geometric shapes such as rectangles, circles, triangles or hexagons, can also be used. Preferably, the electrodes are of the same shape. The first and second electrodes have opposite polarities. For example, the first electrode is a positive electrode while the second electrode is a negative electrode. Providing negative and positive electrodes as the first and second electrodes, respectively, is also useful. The capacitance of the unit capacitor is determined by spacing between the electrodes and the dielectric constant of the dielectric material. For example, a unit capacitor formed with low k dielectric having a line width and spacing equal to 0.1 μm has a cell capacitance of 0.0513 fF and an area of 0.25 μm², resulting in a capacitance of about 2.05 fF/μm². A plurality of unit capacitors can be interconnected to form an array. The unit capacitors can be interconnected, for example, in parallel, series or a combination thereof.

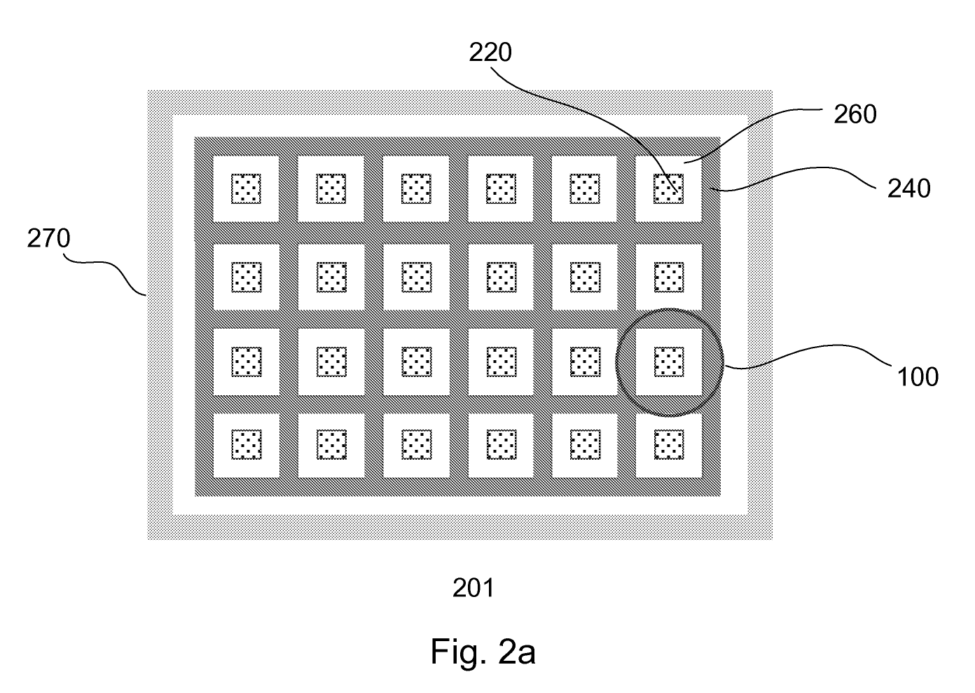

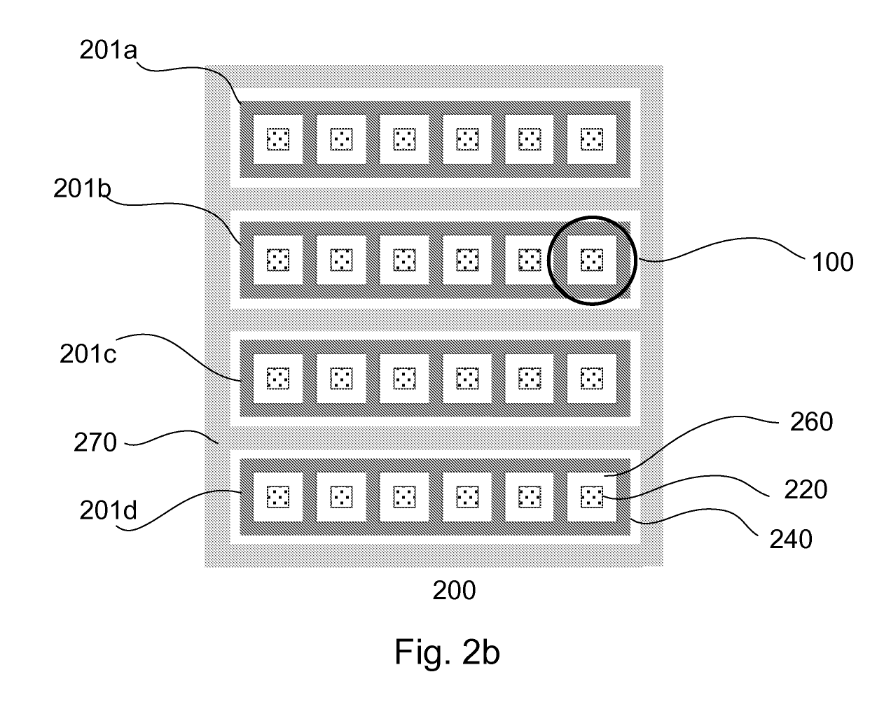

FIGS. 2a-b show capacitors in accordance with other embodiments of the invention. Referring to FIG. 2a, a plurality of unit cells 100 are configured in a capacitor array 201. In one embodiment, the capacitor array comprises m rows and n columns of unit cells. For a two-dimensional array, m and n is equal to or greater than 2. For a one-dimensional array having at least 2 cells, either m or n is greater or equal to 2. Other types of arrays, such as L-shaped or irregular shapes are also useful. The shape of the array, preferably, takes advantage of available space and/or design rules. The unit cells comprise first electrodes 220 and second electrodes 240 separated by a capacitor dielectric 260. In one embodiment, the second or external electrodes form a common electrode of the capacitor array. A plurality of arrays can be provided within a metal layer. The plurality of arrays can be two-dimensional, one-dimensional, irregular shaped or a combination thereof. For example, as shown in FIG. 2b, a capacitor 200 includes a plurality of one-dimensional arrays 201a-d. Multiple arrays can be interconnected so as to achieve the desired capacitance. Alternatively, a plurality of arrays can be formed on different metal layers. Furthermore, it is understood that not all the layers need to have a plurality of arrays and the arrays of the different layers need not be in the same arrangement or form. The arrays can be interconnected to achieve the desired capacitance. For example, the arrays can be interconnected to arrays of the same layer, to arrays of different layers or a combination thereof.

One or more dummy structures 270 can be provided, for example, to improve planarity during leveling of the capacitor electrodes by techniques such as CMP. The dummy structure is provided on the same level as the electrodes. Various types of materials can be used to form the dummy structure. Preferably, the material of the dummy structure has a polishing rate which is the same as or comparable to that of the capacitor electrodes. Preferably, the dummy structure comprises the same material as the electrodes. In one embodiment, where copper electrodes are used, the dummy structure comprises copper. In such case, the dummy structure improves planarity during Cu CMP. The dummy structure can be provided in regions peripheral of the capacitor array to increase the pattern density in these areas. In this way, overpolish at low pattern density areas, such as the edges of the intra-metal capacitor, can be reduced or avoided. Capacitance fluctuation caused by CMP process variation can thereby be lessened or minimized.

In one embodiment, the dummy structure is provided adjacent to at least a portion of the unit cell array. Preferably, the dummy structure is provided adjacent to all portions of the intra-metal capacitor where a long or large copper area is present. More preferably, the dummy structure surrounds the unit cell array. As shown in FIG. 2b, the dummy structure surrounds the plurality of unit cell arrays. The dummy structure can have different line widths and spacings from the intra-metal capacitor. It may also comprise various designs, for example, more than a single line, to provide the appropriate pattern density. The number or design of dummy structures provided can be selected in accordance with design rules.

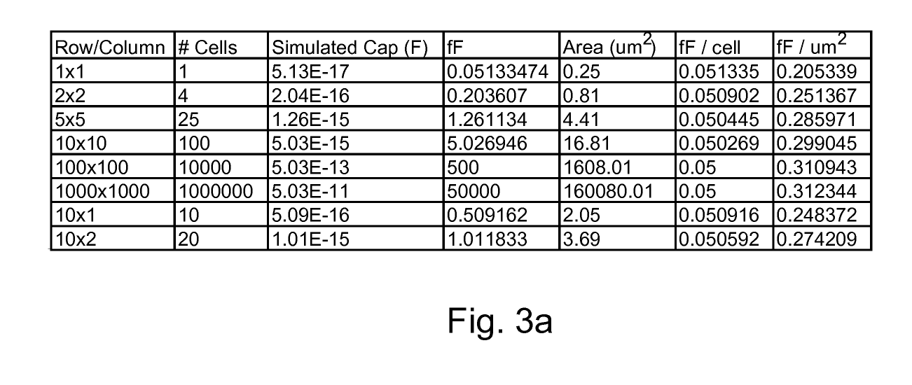

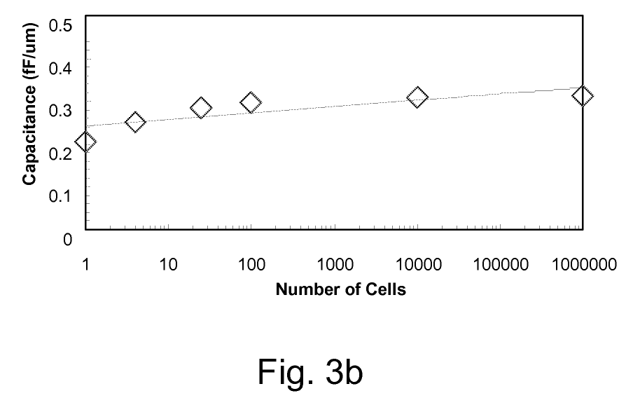

The capacitance of the capacitor is approximately proportional to the number of units cells provided. Capacitance therefore scales with the number of unit cells, enabling easy and accurate prediction of total capacitance. FIG. 3a shows a table of simulated capacitance values of the capacitors having varying numbers of unit cells. The simulated capacitor comprises low-k dielectrics and electrode line width and spacing of 0.1 μm, giving rise to a unit cell with a capacitance of about 5.13e⁻¹⁷ F. From the table, it is fairly simple to design a capacitor with the desired capacitance by providing the appropriate number of unit cells. Furthermore, as shown in FIG. 3b, the capacitance of a unit cell stabilizes when the number of unit cell exceeds about 100.

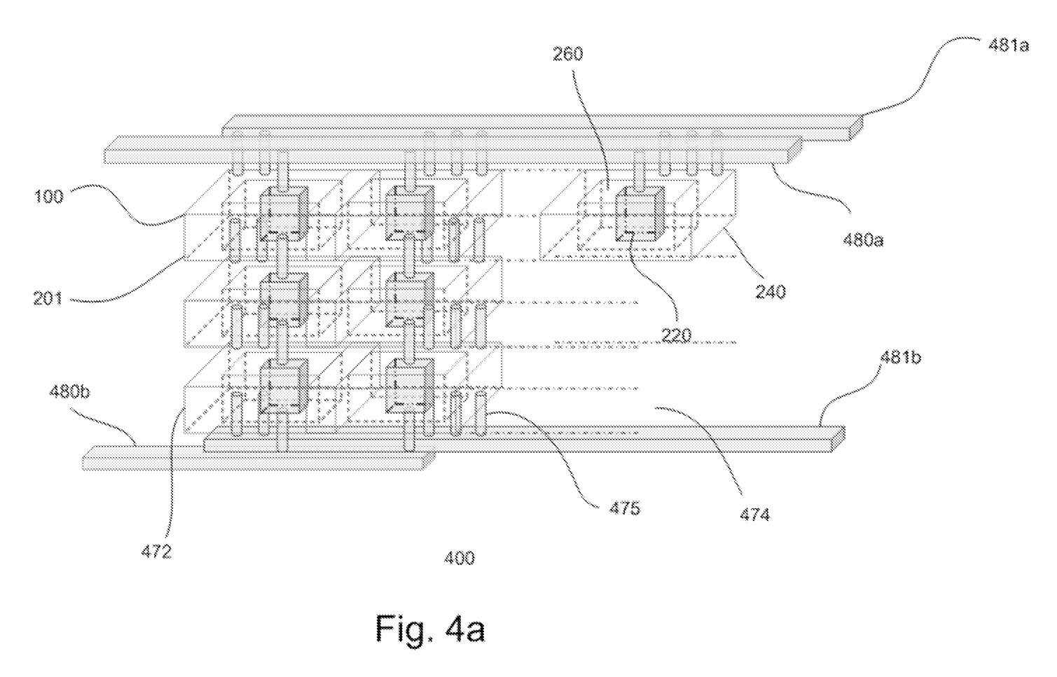

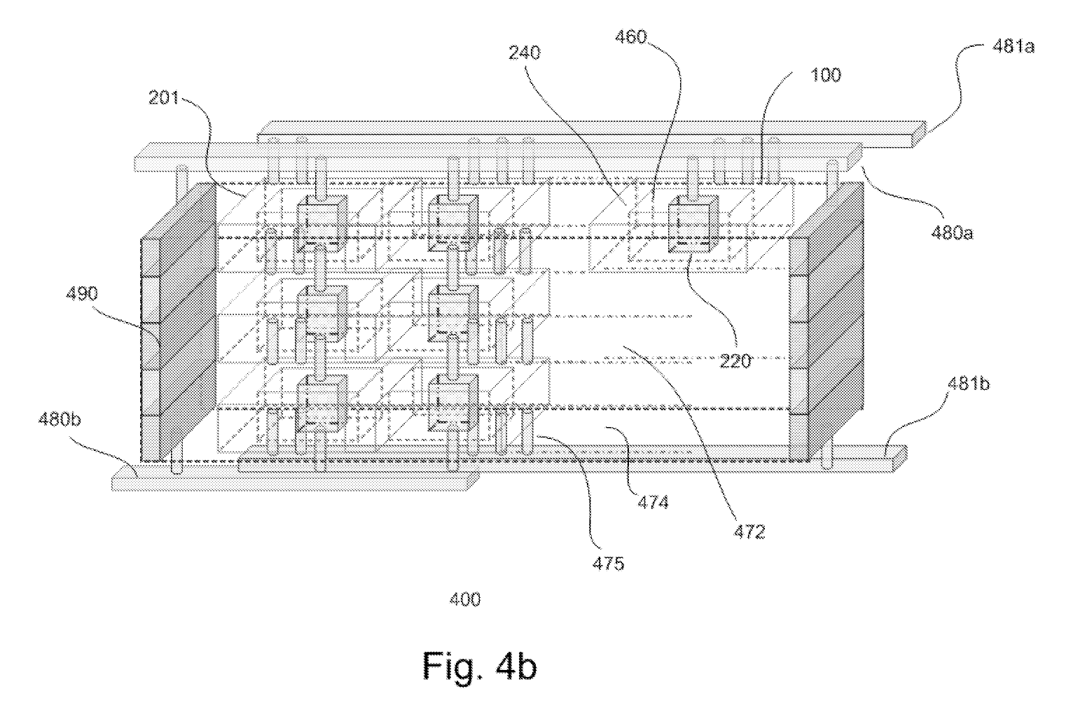

FIGS. 4a-b show capacitor 400 in accordance with other embodiments of the invention. As shown in FIG. 4a, the capacitor comprises a plurality of unit cell arrays 201 disposed on different conductive or metal levels 472 of an IC separated by interlevel dielectric or via levels 474. As shown, the unit cell arrays are one-dimensional unit cell arrays where cells 100 of an array are, for example, arranged in a row. The unit cell arrays, for example, can be identical and stacked in alignment with one another. Alternatively, the unit cell arrays are two-dimensional cell arrays. Other configurations of unit cell arrays, such as having different shapes and/or not being stacked in alignment with one another, can also be useful. The unit cell arrays are interconnected by, for example, contacts 475 formed in the interlevel dielectric layers. For example, the first electrodes of unit capacitors are interconnected and the second electrodes of the unit capacitors are interconnected. Other arrangements are also useful.

As described, the capacitor comprises intra-metal capacitor arrays interconnected to form a multi-layered intra-metal capacitor. The capacitor can be coupled to other circuit elements of the IC as desired by first and second terminals 480a-b and 481a-b. As shown, first and second terminals are located above and below the capacitor arrays. The interconnections can be formed to produce parallel connections to the terminals to achieve the desired capacitance value. For example, the inner capacitor electrodes are coupled to first terminals 480a-b and outer capacitor electrodes are coupled to the second terminals 481a-b. Other coupling configurations are also useful. The capacitor can take advantage of the minimum design rule for the metal layers. To increase the total capacitance of the capacitor, it can be surrounded or “boxed up” by a conductive layer or shield 490, as shown in FIG. 4b. The conductive shield can, for example, comprise conductive materials formed on the metal and via levels. Other conductive materials are also useful. As shown, the conductive box is a solid conductive box. Providing non-solid conductive box is also useful, for example, solid in the metal levels and non solid in the via levels. The conductive box, in one embodiment, is coupled to the same terminals as the inner electrodes (e.g., first terminals). Other coupling configurations can also be useful.

The intra-metal capacitor can be incorporated into ICs and easily integrated into current CMOS processing technologies. The ICs can be any type of IC, for example non-volatile memories, signal processors, or system on chip devices. Other types of ICs are also useful.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. An intra-metal capacitor comprising:
a first electrode;
a second electrode surrounding the first electrode, the first and second electrodes are formed in a device layer; and
a dielectric layer separating the first and second electrodes in the device layer.

2. The intra-metal capacitor in claim 1 wherein the first electrode has a first polarity and the second electrode has a second polarity; the first and the second polarity having opposing polarities.

3. The intra-metal capacitor of claim 1 wherein the first electrode is partially or completely surrounded by the second electrode.

4. The intra-metal capacitor of claim 1 wherein the first electrode and the second electrode comprise geometric shapes.

5. The intra-metal capacitor of claim 1 wherein the first electrode and the second electrode comprise same and/or different geometric shapes.

6. A semiconductor structure comprising:
a contact for interconnection within the structure; and
one or more unit cells, each unit cell comprising an intra-metal capacitor having
a first electrode,
a second electrode substantially surrounding the first electrode, the first and second electrodes are formed in a metal layer, and
a dielectric layer separating the first and second electrodes in the metal layer, wherein the unit cells, each having a unit capacitance, are arranged to produce an overall capacitance.

7. The semiconductor structure of claim 6 wherein the unit cells are arranged to form one or more one dimensional arrays, the one dimensional array having either one row or one column;
the row or column comprising more than one unit cell.

8. The semiconductor structure of claim 6 wherein the unit cells are arranged to form one or more two dimensional arrays, the two dimensional array comprising more than one row and column; the rows and columns each having more than one unit cell.

9. The semiconductor structure of claim 6 wherein the unit cells are arranged to form one dimensional and two dimensional arrays; the one dimensional array having either one row or one column, the row or column comprising more than one unit cell; the two dimensional array comprising more than one row and column, the rows and columns each having more than one unit cell.

10. The semiconductor structure of claim 6 further comprising a dummy structure, the dummy structure surrounding one or more cell units.

11. The semiconductor structure of claims 10 wherein the dummy structure comprises materials having comparable polishing rates to the first and the second electrodes.

12. The semiconductor structure of claim 10 wherein the dummy structure comprises the same materials as the first and the second electrodes.

13. The semiconductor structure of claim 6 wherein the unit cells are formed in more than one metal layer.

14. The semiconductor structure of claim 6 wherein the contact comprises first and second contacts.

15. The semiconductor structure of claim 14 wherein the first contact interconnects the first electrodes and the second contact interconnects the second electrodes.

16. The semiconductor structure of claim 6 wherein the unit cells are surrounded by a conductive shield, the conductive shield is interconnected to the first or second electrode.

17. The semiconductor structure of claim 6 further comprising first and second terminals wherein the first terminal is connected to the first electrode and the second terminal is connected to the second electrode.

18. A method of forming an intra-metal capacitor comprising:
providing a first electrode;
providing a second electrode substantially surrounding the first electrode, the first and second electrodes are formed in a device layer; and
providing a dielectric layer separating the first and second electrodes in the device layer.

19. The method in claim 18 wherein a plurality of the intra-metal capacitor is provided to form one or more one dimensional arrays, the one dimensional array having either one row or one column; the row or column comprising more than one unit cell.

20. The method in claim 18 wherein a plurality of intra-metal capacitors is provided to form one or more two dimensional arrays, the two dimensional array comprising more than one row and column; the rows and columns each having more than one unit cell.

21. The method in claim 18 wherein the intra-metal capacitor is formed in more than one metal layer.

22. The method in claim 18 wherein a contact is further provided, the contact comprising a plurality of terminals to the intra-metal capacitor.

23. An integrated circuit (IC) comprising:
an intra-metal capacitor, the intra-metal capacitor comprising
a first electrode,
a second electrode substantially surrounding the first electrode, and
a dielectric layer disposed in the space between the first and second electrodes,
wherein an increase in the space between the electrodes on any one side results in a corresponding decrease on the opposite side.
